(19) United States
(12) Patent Application Publication
(10) Pub. No.: US 2026/0371474 A1
(43) Pub. Date: Nov. 19, 2026

(54) HEAT DISSIPATION STRUCTURE FOR HIGH-POWER CHIP POWER SUPPLY MODULE

(71) Applicant: MetaPWR Electronics Co., Ltd., Shanghai (CN)

(72) Inventors: Jingdi ZHANG, Shanghai (CN); Sibin LIU, Shanghai (CN); Qingdong CHEN, Shanghai (CN)

(73) Assignee: MetaPWR Electronics Co., Ltd., Shanghai (CN)

(21) Appl. No.: 19/672,739

(22) Filed: May 11, 2026

(30) Foreign Application Priority Data
May 13, 2025 (CN) 202510612591.6

(51) Int. Cl. H05K 1/02

(52) U.S. Cl. CPC H05K 1/0204; H05K 1/0271; H05K 2201/064; H05K 2201/10545

(57) ABSTRACT

A heat dissipation structure for a high-power chip vertical power supply module comprises a top heat dissipation device, a thermal interface material, an XPU module, a system mainboard, a power supply module, and a bottom heat dissipation device; the bottom heat dissipation device comprises at least one vapor chamber, and the vapor chamber is connected to a heat dissipation surface of the power supply module to uniformly spread heat for the module, and is connected to the top heat dissipation device through a longitudinal heat-conducting member. A connection between the longitudinal heat-conducting member and the vapor chamber not only secures the vapor chamber, but also effectively guides the heat generated by the power supply module to the top heat dissipation device.

### CROSS-REFERENCE TO RELATED APPLICATIONS

This application claims the priority benefit of Chinese patent application CN202510612591.6 filed on May 13, 2025. The entirety of the above-mentioned patent application is hereby incorporated by reference herein and made a part of this specification.

### BACKGROUND

As artificial intelligence computing power continues to increase, the power consumption of computing chips such as CPUs, TPUs, and GPUs (collectively referred to hereinafter as XPUs) is also increasing, and the current correspondingly continues to rise. In a conventional smart card, the power supply module and the XPU are located on the same side, i.e., lateral power delivery (LPD). However, this arrangement can no longer satisfy the trend toward increasingly higher current. Accordingly, the power supply module has begun to shift to vertical power delivery (VPD), in which the power supply module is positioned directly below the XPU.

Due to the increase in the number of digital signals, the traditional vertically inserted PCIE card has become limited in signal and power handling capability. Large smart cards have therefore begun to evolve from an upright configuration to a flat configuration, such as OAM. Hereinafter, such flat configurations are collectively referred to as OAM, but are not limited to the OAM standard. Because the height between the flat smart card and the system mainboard is extremely limited, typically between 5 mm and 10 mm, and this height must accommodate both the thickness of the power supply module and the thickness of the heat dissipation device for dissipating heat from the power supply module, the space available for the heat dissipation device is extremely limited. Moreover, the OAM-VPD industry is still in an exploratory stage, and no mature technology yet exists. The simplest existing approach is still to transfer the heat generated by the power supply module to the smart card mainboard, then transfer the heat through vias to one side of the XPU, where it is dissipated by the heat sink of the XPU. Therefore, in the related art, the high-frequency power semiconductors of the power supply module, referred to as MOS herein, may be arranged on the side of the module close to the smart card mainboard (the MOS usually being in the form of DrMOS or SPS). Such a structure not only results in a large thermal resistance for heat dissipation of the power supply module, but also increases the temperature of the XPU, thereby affecting the processing capability of the XPU.

Accordingly, the present application is the first to propose an effective and practical integrated solution of the power delivery and cooling of the OAM-VPD.

### SUMMARY

In view of the above, one of the objectives of the application is to provide a heat dissipation structure for a high-power chip power supply module, the high-power chip power supply module comprising:

A first mainboard, comprising a first surface and a second surface opposite to each other.

A high-power chip module disposed on the first surface.

A vertical power supply module having a top surface fixed to the second surface and electrically connected to the first mainboard, the vertical power supply module including at least one heat-generating power component.

A top heat dissipation device thermally coupled to the high-power chip module and vertically aligned with the high-power chip module.

The bottom surface of the vertical power supply module defines a heat dissipation surface, the at least one heat-generating power component is disposed adjacent to the heat dissipation surface.

The bottom heat dissipation device includes a bottom heat-conducting portion and a vertical heat-conducting portion; the bottom heat-conducting portion being thermally coupled to the heat dissipation surface of the vertical power supply module, the vertical heat-conducting portion being thermally coupled to the top heat dissipation device, such that the bottom heat-conducting portion is thermally coupled to the top heat dissipation device through the vertical heat-conducting portion.

Preferably, the top heat dissipation device comprises a top liquid cooling plate and a thermal interface material, the thermal interface material comprises a thermal grease, a thermal pad, or a phase-change material.

The top heat dissipation device is thermally coupled to the high-power chip module and to the vertical heat-conducting portion of the bottom heat dissipation device through the thermal interface material.

Preferably, the bottom heat dissipation device is U-shaped and includes two vertical heat-conducting portions, the two vertical heat-conducting portions are respectively connected to two ends of the bottom heat-conducting portion and thermally coupled to a side surface of the top heat dissipation device.

Preferably, the bottom heat-conducting portion includes a stiffening plate, the stiffening plate including a middle slot and a plurality of boss stiffeners disposed in the middle slot, each of the plurality of boss stiffeners including a boss disposed on a top surface thereof.

Each of the boss stiffeners includes a top surface and a bottom surface, and each of the plurality of boss stiffeners includes a boss disposed on a top surface thereof; the top surface of each boss is connected to the second surface of the first mainboard.

The vertical power supply module is disposed between adjacent ones of the plurality of boss stiffeners.

Preferably, the bottom heat dissipation device further includes a transition portion disposed between the vertical heat-conducting portion and the bottom heat-conducting portion.

Each of the vertical heat-conducting portion and the bottom heat-conducting portion is provided with a cavity.

The transition portion disposes a groove in communication with the cavity of the vertical heat-conducting portion and the cavity of the bottom heat-conducting portion.

Preferably, an inner wall of the groove is made of a metal mesh or a sintered copper powder.

An opening of the groove faces the heat dissipation surface of the vertical power supply module.

Preferably, the cavity is filled with a phase-change material.

Preferably, the bottom heat-conducting portion further includes a bottom vapor chamber thermally coupled to the heat dissipation surface of the vertical power supply module.

Bottom surfaces of the plurality of boss stiffeners are fixed to and thermally coupled to the bottom vapor chamber.

Preferably, the bottom surfaces of the plurality of boss stiffeners are fixed to and thermally coupled to the bottom vapor chamber by an epoxy resin adhesive or a silicone adhesive.

The bottom heat-conducting portion further includes two horizontal heat-conducting portions respectively connected to the two vertical heat-conducting portions.

Bottom surfaces of the two horizontal heat-conducting portions are thermally coupled to the bottom vapor chamber.

The two horizontal heat-conducting portions and the two vertical heat-conducting portions are metal sheets.

Preferably, the bottom surfaces of the two horizontal heat-conducting portions are thermally coupled to the bottom vapor chamber by welding or by a thermally conductive adhesive.

Preferably, the vertical heat-conducting portion is a vertical vapor chamber connected to the bottom vapor chamber.

A cavity defined in the vertical vapor chamber is in communication with a cavity defined in the bottom vapor chamber.

The cavities are filled with a phase-change material.

Preferably, the vertical vapor chamber is connected to the bottom vapor chamber by a brazing, a reflow soldering, or a laser welding.

The bottom heat dissipation device includes a U-shaped heat pipe assembly formed by a plurality of U-shaped heat pipes and a bottom metal sheet disposed on an upper surface of the U-shaped heat pipe assembly.

A bottom surface of the bottom metal sheet is thermally coupled to the U-shaped heat pipe assembly.

The heat dissipation surface of the vertical power supply module and the bottom surfaces of the plurality of boss stiffeners are thermally coupled to a top surface of the bottom metal sheet.

Opposite side portions of the U-shaped heat pipe assembly are thermally coupled to the top heat dissipation device.

Preferably, the U-shaped heat pipe assembly includes a plurality of cavities filled with a phase-change material; wherein a contact width between the U-shaped heat pipe assembly and the top heat dissipation device is greater than or equal to 25 mm.

Preferably, the high-power chip power supply module further comprises a capacitor disposed on the second surface of the first mainboard, the capacitor is arranged corresponding to the plurality of boss stiffeners and disposed between adjacent bosses.

Preferably, the bottom heat dissipation device further includes screws.

The screws extend through screw holes formed in the vertical heat-conducting portion and screw holes formed in the top heat dissipation device to fix and thermally connect to the vertical heat-conducting portion and the top heat dissipation device.

Preferably, the bottom heat dissipation device further includes screws and fasteners.

The top heat dissipation device, the vertical heat-conducting portion, and the fasteners are arranged in sequence.

The screws extend through screw holes formed in the fasteners and screw holes formed in the top heat dissipation device to fix and thermally connect to the vertical heat-conducting portion and the top heat dissipation device.

Preferably, the bottom surface of each of the plurality of boss stiffeners disposes a fixing groove.

A top surface of the bottom vapor chamber includes a fixing boss corresponding to the fixing groove.

The fixing groove and the fixing boss are assembled together.

Preferably, the fixing groove and the fixing boss are assembled by a vacuum diffusion welding or a hot-press sintering.

Preferably, the high-power chip power supply module further comprises a second mainboard and a high-speed signal connector disposed between the first mainboard and the second mainboard.

The first mainboard is electrically connected to the second mainboard through the high-speed signal connector.

The stiffening plate further includes a side slot configured to allow the high-speed signal connector to pass therethrough.

Preferably, the stiffening plate is fixed to the second mainboard by screws.

Preferably, opposite sides of the first mainboard dispose respective clearance regions configured to allow the vertical heat-conducting portion to bypass the first mainboard and be thermally coupled to the top heat dissipation device.

Preferably, opposite sides of the top heat dissipation device dispose respective notches configured to receive the vertical heat-conducting portion.

Preferably, a contact width between the vertical heat-conducting portion and the top heat dissipation device is greater than or equal to 10 mm.

Compared with the related art, the application has the following beneficial effects:
(1) By arranging the heat-generating components in the vertical power supply module at positions other than a pin side (a contact side of a smart card mainboard), and by providing an additional heat dissipation path for the vertical power supply module, not only a heat dissipation thermal resistance of the vertical power supply module is reduced and the temperature is lowered, but also the heat of the vertical power supply module is prevented from being transferred to the XPU and affecting its operating performance.
(2) Through the cooperation of a lateral heat-conducting portion and a longitudinal heat-conducting portion of the bottom heat dissipation device, the heat of the vertical power supply module is more effectively transferred to a top heat dissipation device within a limited height space. And through a heat transfer composite design of the bottom heat dissipation device, a fastening force, a fitting performance, and a heat dissipation efficiency of the bottom heat dissipation device are improved.
(3) By providing a liquid-cooling circulation system, a thickness of an entire module is further reduced while ensuring heat dissipation.

### DESCRIPTION OF DRAWINGS

FIG. 1 is a schematic diagram of the prior art;

FIGS. 2A to 2F are schematic diagrams of Embodiment 1;

FIGS. 3A to 3E are schematic diagrams of Embodiment 2;

FIGS. 4A to 4D are schematic diagrams of Embodiment 3.

### DETAILED DESCRIPTION

One of the cores of the present application is to provide a heat dissipation structure for a high-power chip power supply module. By arranging the heat-generating components in the power supply module at positions other than the pin side, an additional heat dissipation path is provided, thereby preventing the heat generated by the power supply module from affecting the operation of the XPU. In addition, through the cooperation of a bottom lateral heat-conducting member and a longitudinal heat-conducting member, the heat of the power supply module is more effectively transferred to the top heat dissipation device while both a heat transfer performance and a mechanical fastening capability are taken into account.

Technical solutions in the embodiments of the present disclosure will be clearly and completely described below with reference to the accompanying drawings in the embodiments of the present disclosure. Apparently, the described embodiments are merely some rather than all of the embodiments of the present disclosure. All other embodiments obtained by a person of ordinary skill in the art based on the embodiments of the present disclosure without creative efforts shall fall within the protection scope of the present disclosure.

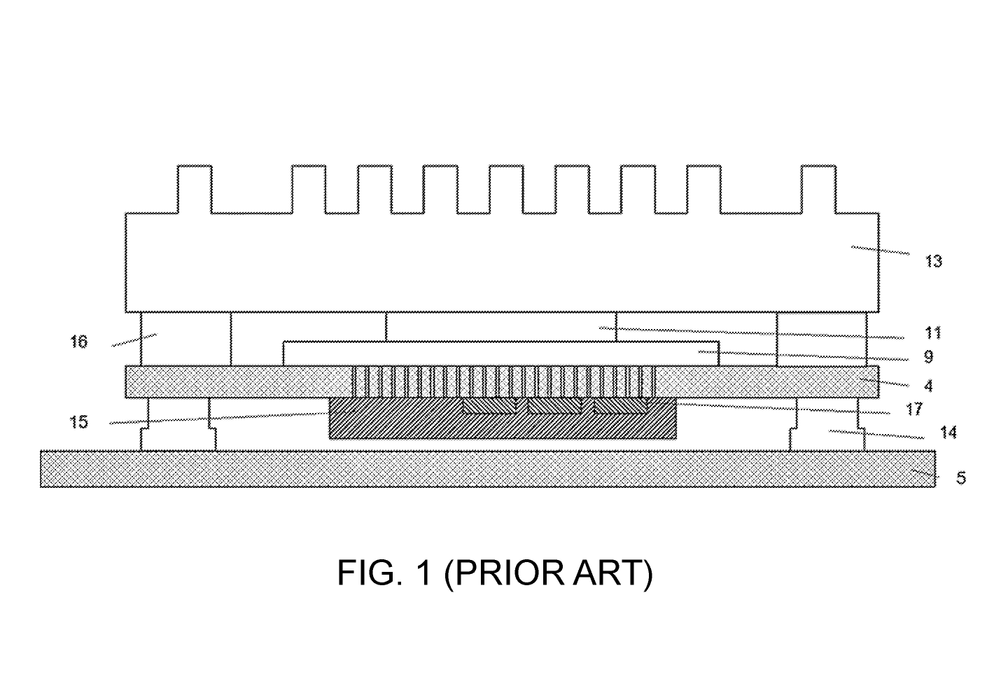

As shown in FIG. 1, a currently commonly used structure and a heat dissipation structure of a high-power chip power supply module. The high-power chip power supply module includes a first mainboard 4, a second mainboard 5, a high-power chip module 3, high-speed signal connectors 14, a horizontal power supply module 16, and a vertical power supply module 15. The first mainboard 4 here is a smart card mainboard. The high-power chip module is mounted on an upper surface of the first mainboard 4. The high-power chip module includes at least one XPU die 11 and an XPU substrate 9. The XPU die 11 is disposed on an upper surface of the XPU substrate 9, and a lower surface of the XPU substrate 9 is attached to and electrically connected to the upper surface of the first mainboard 4. At least one high-speed signal connector 14 is arranged on each of at least two sides of a lower surface of the first mainboard 4, and the high-power chip module is directly or indirectly electrically connected to the second mainboard 5 (i.e., the system mainboard) through the high-speed signal connectors 14. The horizontal power supply module 16 is arranged on the upper surface of the first mainboard 4 and is horizontally arranged relative to the high-power chip module, thereby supplying power to the XPU in a horizontal power supply mode. The vertical power supply module 15 is arranged on the lower surface of the first mainboard 4 and vertically corresponds to the high-power chip module (i.e., the projections of the vertical power supply module 15 and the XPU on the upper surface of the first mainboard at least partially overlap). The vertical power supply module 15 supplies power to the XPU in a vertical power supply mode. This structure enables the vertical power supply module 15 and the XPU to be connected over the shortest distance, such that the transmission impedance therebetween is low and the dynamic response of the power supply module to load variation is fast, thereby well satisfying the dynamic characteristic requirements of the XPU. The high-power chip power supply module further includes a top heat dissipation device 13 disposed above the XPU and attached to a heat dissipation surface of the XPU, thereby providing an upward heat dissipation path for the XPU. In addition, the top heat dissipation device 13 may be attached to both the heat dissipation surface of the XPU and a heat dissipation surface of the horizontal power supply module 16, thereby simultaneously providing an upward heat dissipation path for both the XPU and the horizontal power supply module 16. However, due to the height limitation between the first mainboard 4 and the second mainboard 5, no heat dissipation device can be installed for the vertical power supply module 15. Therefore, a heat dissipation structure for a power supply module using a vertical power supply mode is urgently needed.

### Embodiment 1

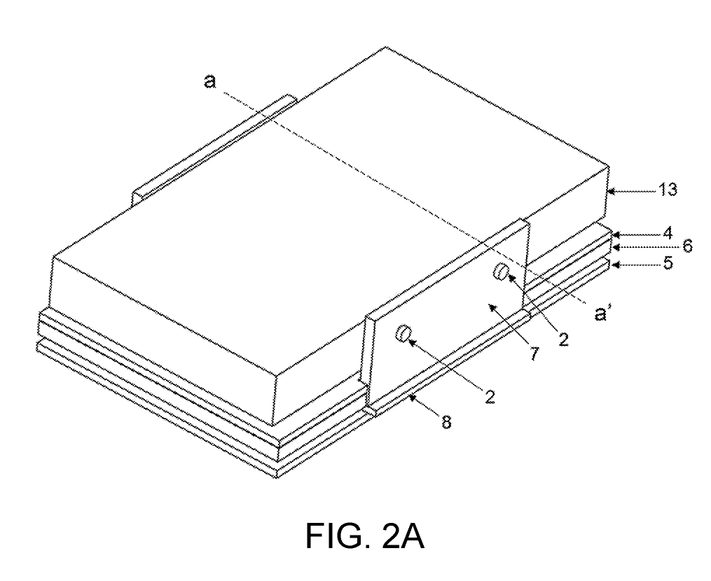

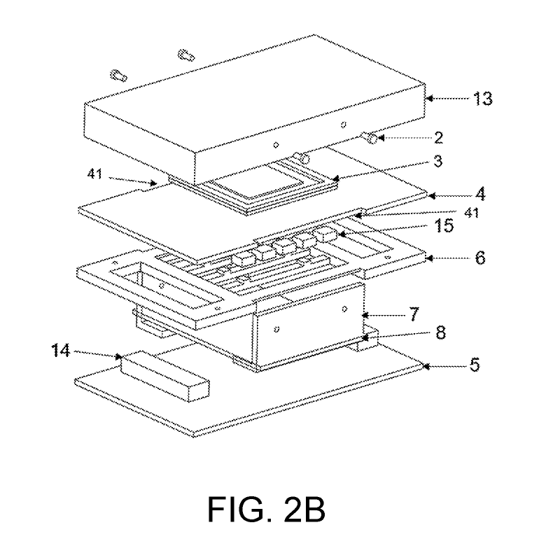

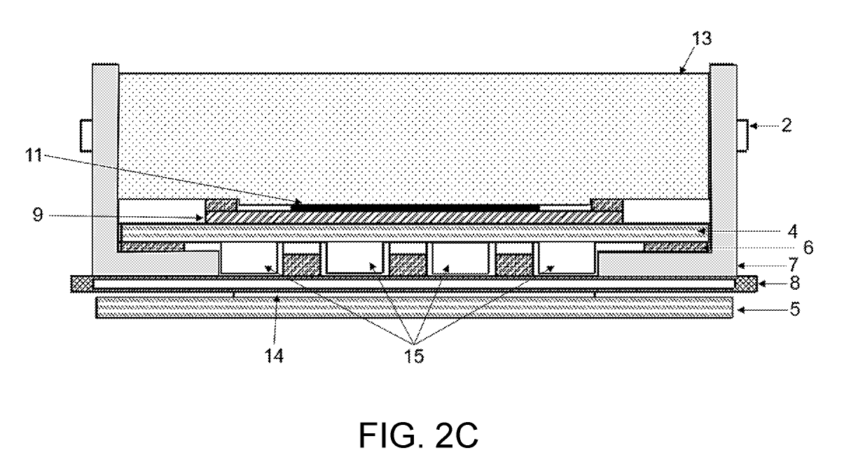

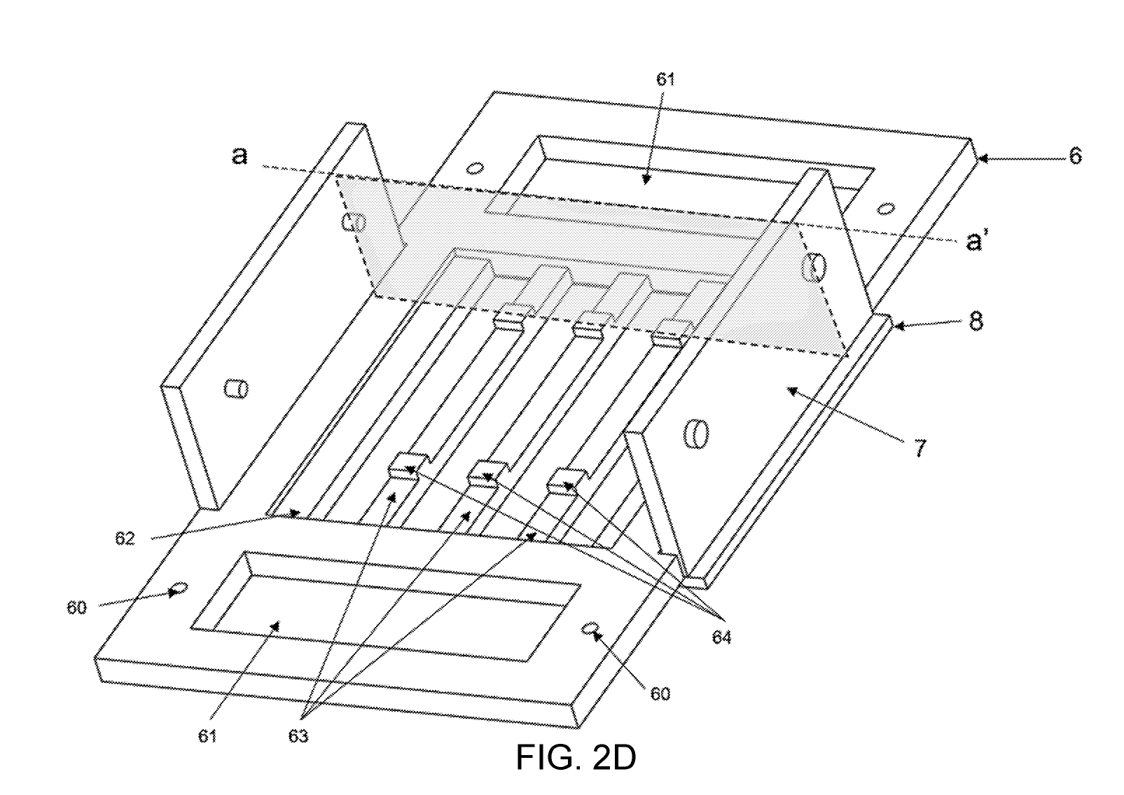

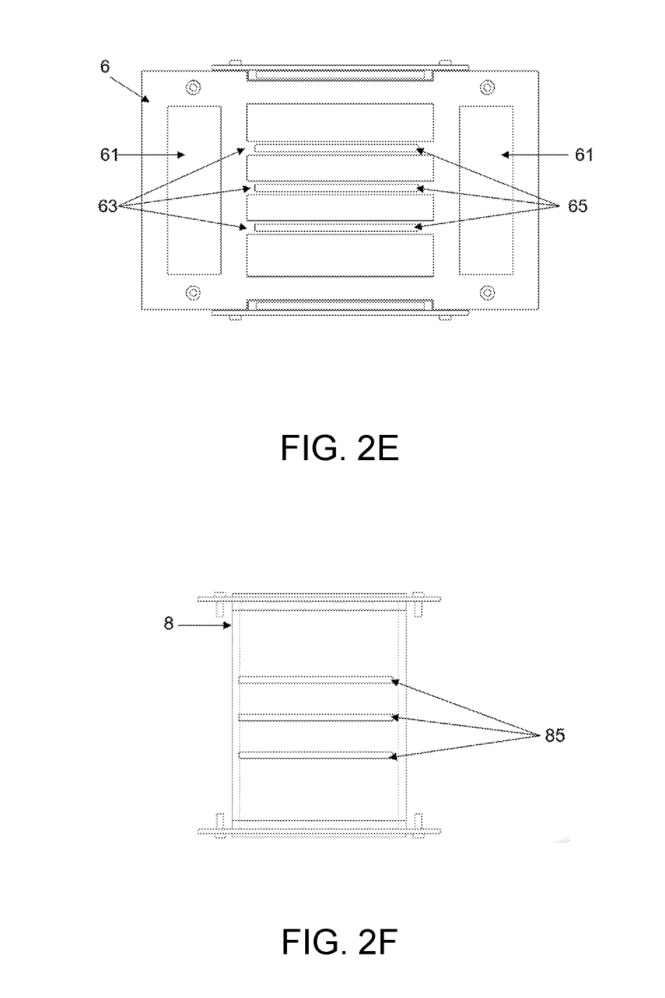

As shown in FIGS. 2A to 2D, FIG. 2A is a schematic diagram of a heat dissipation structure for a high-power chip power supply module disclosed in this embodiment, FIG. 2B is an exploded view of FIG. 2A, FIG. 2C is a schematic sectional view taken along aa' in FIGS. 2A and 2D, is a schematic structural diagram of a heat transfer composite assembly. Referring to FIGS. 2B and 2C, the high-power chip power supply module shown in this embodiment includes a first mainboard 4, a second mainboard 5, a high-power chip module 3, high-speed signal connectors 14, a horizontal power supply module 16, and a vertical power supply module 15. The arrangement of these components is the same as that shown in FIG. 1 and will not be repeated herein. A power consumption of a high-power XPU here is usually greater than 500 W, and the high-power chip module is directly or indirectly electrically connected to the second mainboard 5 through the high-speed signal connectors 14. The vertical power supply module 15 is arranged on the lower surface of the first mainboard 4 and transmits a low-voltage, high-current supply from the lower surface to the upper surface of the first mainboard 4 through vias penetrating the first mainboard 4, thereby supplying power to the XPU. The vertical power supply module 15 may be an integrated high-current module or a plurality of low-current modules. The low-current modules are arranged on the first mainboard 4 in an array, and the plurality of low-current modules are electrically connected through the first mainboard 4. An overall power consumption of all the vertical power supply modules 15 is usually greater than 50 W.

In this embodiment, the top heat dissipation device 13 is a main liquid cooling plate disposed above the XPU and attached to the heat dissipation surface of the XPU, thereby providing an upward heat dissipation path for the XPU. The high-power chip power supply module shown in this embodiment further includes a heat transfer composite assembly. As shown in FIG. 2D, the heat transfer composite assembly includes screws 2, a stiffening plate 6, longitudinal heat-conducting members 7, and a bottom vapor chamber 8. The top heat dissipation device 13 may further dissipate heat for the vertical power supply module 5 through the heat transfer composite assembly. A thermal interface material (not shown) is arranged between the bottom vapor chamber 8 and a heat dissipation surface of the vertical power supply module 15, so as to equalize the heat generated by the vertical power supply module 15 within the bottom vapor chamber 8. A surface of the vertical power supply module 15 that is electrically connected to the first mainboard 4 is defined as the pin side or a top side. The power semiconductor components, collectively referred to as MOS 17, are the heat-generating components with the highest heat density in the vertical power supply module 15. Therefore, the MOS 17 should be arranged adjacent to a surface other than the pin side, such as a side surface and/or a bottom surface of the vertical power supply module 15, which are collectively referred to herein as the heat dissipation surface. In this embodiment, a position of the MOS 17 in the vertical power supply module 15 should be attached to the bottom vapor chamber 8. The stiffening plate 6 is fixed to the first mainboard 4 through screw holes 60 and screws. The stiffening plate 6 adopts a segmented clearance arrangement and includes side slots 61 and a middle slot 62, wherein the side slots 61 are used for accommodating the high-speed signal connectors 14. Boss stiffeners 63 are arranged in the middle slot 62. A plurality of boss stiffeners 63 are arranged in parallel, and two ends thereof are connected to two opposite side surfaces of the middle slot 62. Bottom surfaces of the boss stiffeners 63 are attached to a top surface of the bottom vapor chamber 8. Each boss stiffener 63 is provided with a plurality of boss structures 64, and top surfaces of the plurality of boss structures 64 are attached to the first mainboard 4. The vertical power supply module 15 and capacitors are arranged on the bottom surface of the first mainboard 4. The vertical power supply module 15 is arranged between the boss stiffeners 63, and the capacitors correspond to the boss stiffeners 63 while avoiding the positions of the boss structures 64.

A fixing groove 65 is further arranged on the bottom surface of the boss stiffener 63, as shown in FIG. 2E. The fixing groove 65 is a strip-shaped and corresponds to the shape of the cross section of the bottom surface of the boss stiffener 63, but is not limited thereto. Correspondingly, a fixing boss 85 is arranged on the top surface of the bottom vapor chamber 8. The fixing boss 85 corresponds in position and shape to the fixing groove 65. The fixing boss 85 adopts a micron-scale boss structure and is distributed in an array on the top surface of the bottom vapor chamber 8. The fixing groove 65 and the fixing boss are metallurgically bonded by a vacuum diffusion welding or a hot-press sintering, thereby improving a shear strength of the vapor chamber. In addition, the bottom vapor chamber 8 and the boss stiffener 63 may also be connected by a high-strength adhesive according to usage requirements. The adhesive types include, but are not limited to, epoxy resin adhesive and silicone adhesive. In this embodiment, the boss stiffener 63, on the one hand, enables fixation to the bottom vapor chamber 8 and reduces deformation of the vapor chamber; on the other hand, the boss structure 64 provides at least one support point for the first mainboard 4 below the XPU, thereby effectively preventing warpage deformation of the first mainboard 4 caused by a downward pressure of the top heat dissipation device 13.

Referring to FIGS. 2B, 2C, and 2D, each longitudinal heat-conducting member 7 is an L-shaped metal plate with a rectangular horizontal cross section and is arranged on two opposite sides of the first mainboard 4. Clearance regions 41 are formed on both sides of the first mainboard 4 to facilitate positioning of the longitudinal heat-conducting members 7. Each longitudinal heat-conducting member 7 includes a vertical heat-conducting portion and a horizontal heat-conducting portion. The longitudinal heat-conducting member 7 passes through the clearance region 41, and a bottom surface of the horizontal heat-conducting portion is fixed to the bottom vapor chamber 8. The fixing manner may be welding or bonding with thermally conductive adhesive. The vertical heat-conducting portion is fixedly connected to the top heat dissipation device 13 through screws. Specifically, the longitudinal heat-conducting member 7 includes screw holes mated with the screws 2, and the top heat dissipation device 13 includes screw holes mated with the screws 2. The screws 2 press and fix the vertical heat-conducting portion onto the top heat dissipation device 13, thereby providing mechanical fastening and reducing thermal resistance for heat conduction. In addition, a thermal interface material (not shown) may be arranged between the vertical heat-conducting portion and the side surface of the top heat dissipation device 13, thereby further reducing the thermal resistance therebetween.

In this embodiment, after the heat generated by the vertical power supply module 15 is equalized by the vapor chamber 8, the heat is conducted upward through the L-shaped metal plates and transferred to the top heat dissipation device 13 through the thermal interface material. When the heat from the vertical power supply module 15 is transferred to the bottom vapor chamber 8, the phase-change medium inside the bottom vapor chamber 8 is heated and changes from a liquid state to a gaseous state, thereby rapidly spreading heat throughout the entire bottom vapor chamber 8. The heat is then released and cooled through heat transfer by the horizontal heat-conducting portion, whereupon the phase-change medium changes from the gaseous state back to the liquid state and returns by diffusion through a capillary structure to the heat source region covered by the vertical power supply module 15. Through this repeated cycle, the heat generated by the vertical power supply module 15 is dissipated through the bottom vapor chamber 8, the longitudinal heat-conducting members 7, and the top heat dissipation device 13.

### Embodiment 2

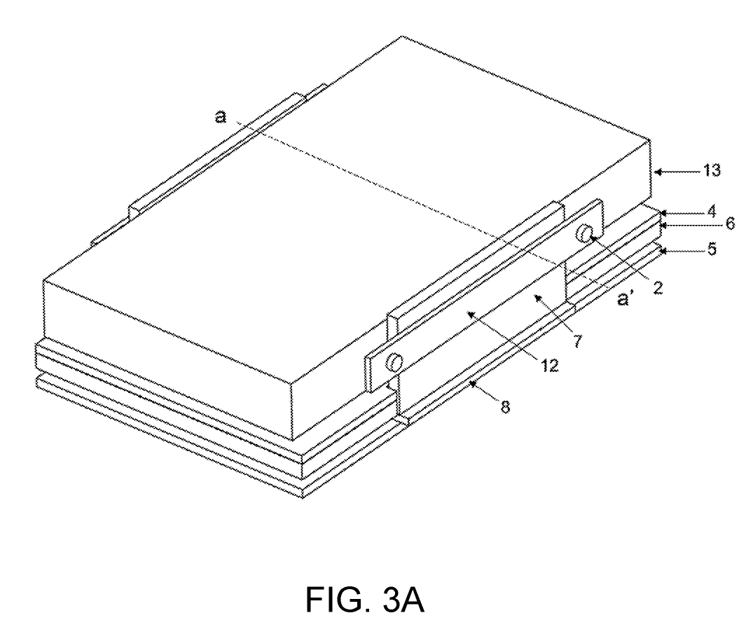

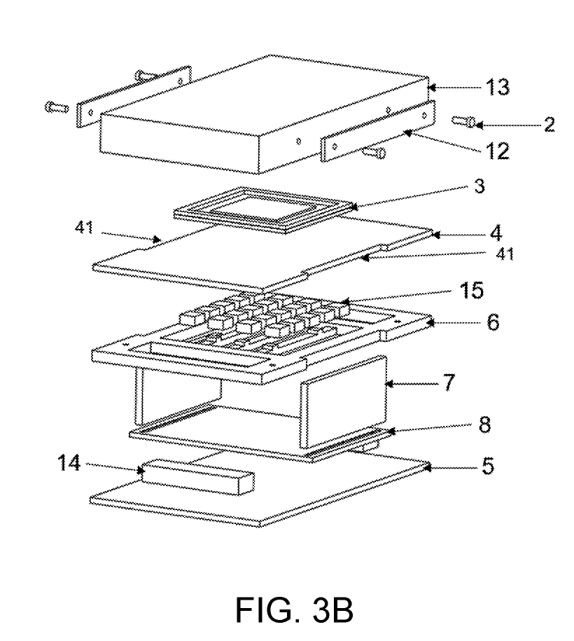

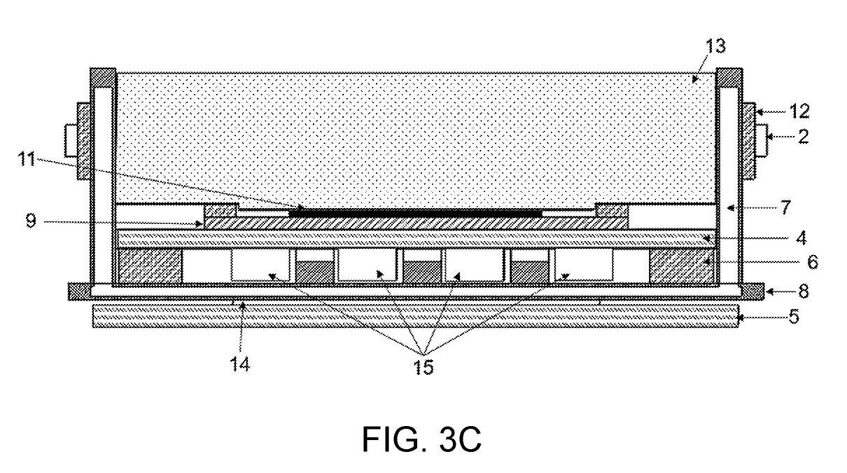

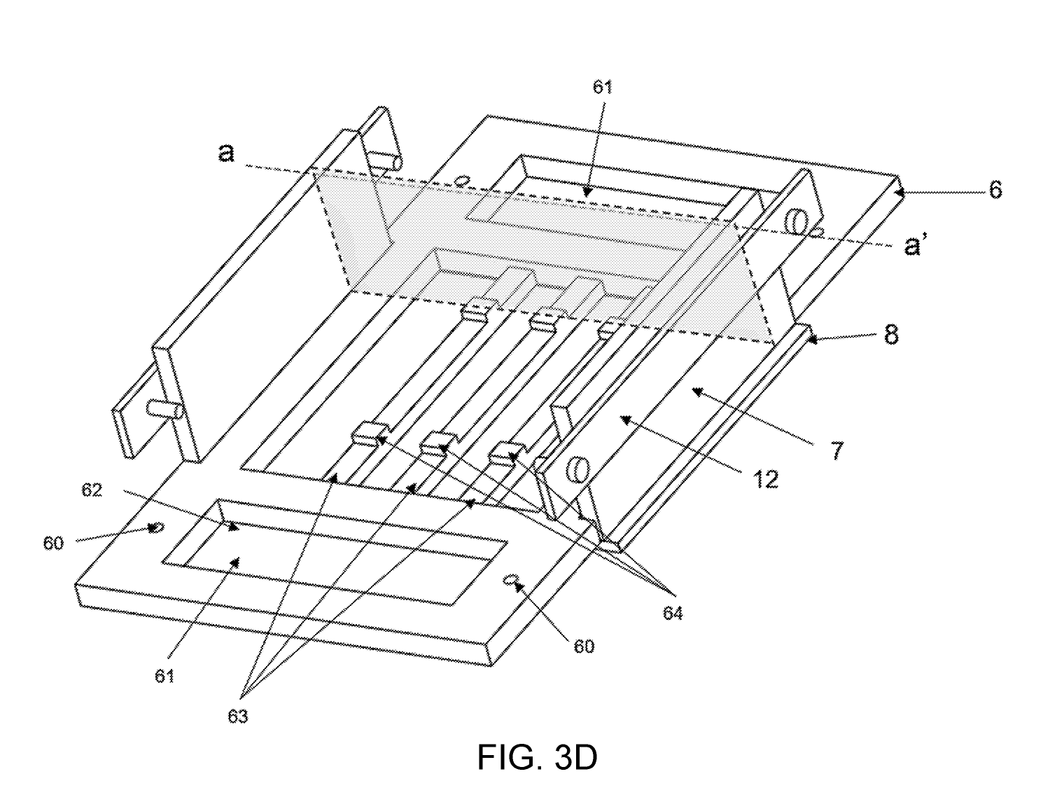

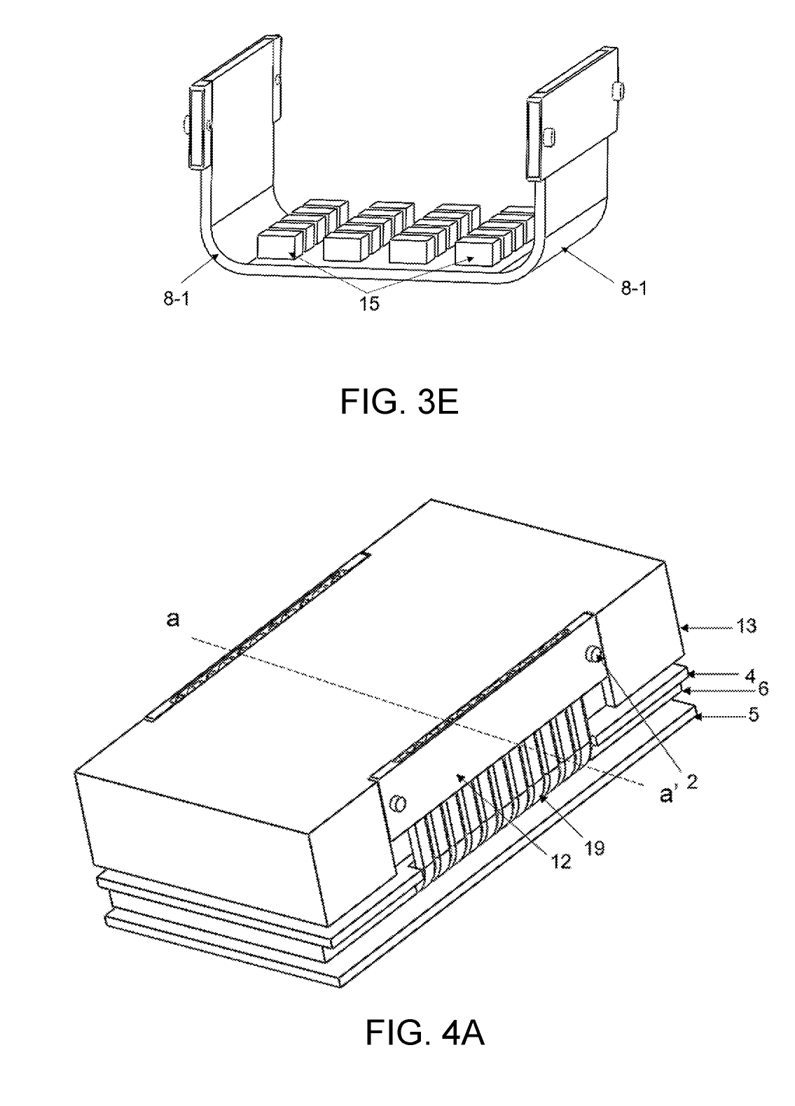

In order to further improve a heat dissipation capability of the high-power chip module, the longitudinal heat-conducting members 7 in this embodiment are vapor chambers, as shown in FIGS. 3A to 3C, wherein FIG. 3A is a perspective view of the high-power chip module, FIG. 3B is an exploded view of FIG. 3A, and FIG. 3C is a side sectional view taken along aa'. The heat transfer composite assembly of this embodiment includes a bottom vapor chamber 8, longitudinal heat-conducting members 7, the stiffening plate 6, fasteners 12, and screws 2, as shown in FIG. 3D.

Each longitudinal heat-conducting member 7 is I-shaped with a rectangular horizontal cross section and is arranged on two opposite sides of the first mainboard 4. A lower side of the longitudinal heat-conducting member 7 is vertically welded to the bottom vapor chamber 8 and is connected to a same cavity as the bottom vapor chamber 8, thereby forming a U-shaped vapor chamber assembly. The welding manner includes, but is not limited to, brazing, reflow soldering, and laser welding. The longitudinal heat-conducting member 7 in the U-shaped vapor chamber assembly is fixedly connected to the top heat dissipation device 13 through the fasteners 12. Specifically, the top heat dissipation device 13 includes screw holes mated with the screws 2. The fasteners 12 and the screws 2 press and fix the longitudinal heat-conducting member 7 onto the top heat dissipation device 13, thereby providing mechanical fastening between the longitudinal heat-conducting member 7 and the top heat dissipation device 13 while reducing the thermal resistance therebetween. In addition, the thermal interface material (not shown) may also be arranged between the longitudinal heat-conducting member 7 and the top heat dissipation device 13, thereby further reducing the thermal resistance therebetween. The structure of the stiffening plate 6 shown in this embodiment is the same as that in the previous embodiment. Likewise, by providing grooves in the bottom surface of the stiffening plate 6 and bosses on the top surface of the bottom vapor chamber 8 for fixed connection, the same technical effects can be achieved and will not be repeated herein.

In this embodiment, the U-shaped vapor chamber assembly formed by the longitudinal heat-conducting members 7 and the bottom vapor chamber 8 is a common-cavity hollow structure. The cavity structure is filled with the phase-change medium, as shown in FIG. 3C. When the heat generated by the vertical power supply module 15 is transferred to the bottom vapor chamber 8, the internal phase-change medium is heated and changes from the liquid state to the gaseous state, then travels through a U-shaped cavity to a top of the longitudinal heat-conducting members 7. After being cooled by the top heat dissipation device 13, the phase-change medium changes from the gaseous state back to the liquid state and returns to the bottom vapor chamber 8. Through this repeated cycle, the heat generated by the vertical power supply module 15 is dissipated through the bottom vapor chamber 8, the longitudinal heat-conducting members 7, and the top heat dissipation device 13. The continuous U-shaped cavity, together with the phase-change medium, effectively reduces the thermal resistance between the vertical power supply module 15 and the top heat dissipation device 13, such that most of the heat generated by the vertical power supply module 15 is transferred to the top heat dissipation device 13 through the heat transfer composite assembly, thereby preventing excessive heat from being transferred to the XPU through the first mainboard 4 and thus reducing the thermal burden on the heat dissipation of the XPU. In addition, in order to ensure effective heat exchange of the phase-change medium in the U-shaped vapor chamber assembly, a contact width between the longitudinal heat-conducting members 7 and the top heat dissipation device 13 must be greater than or equal to 10 mm, and sufficient thickness must be provided to reduce the resistance imposed by the U-shaped cavity on the diffusion of the phase-change medium.

Considering that the power supply module is located below the top heat dissipation device 13, the U-shaped vapor chamber assembly may also adopt an integral structure, as shown in FIG. 3E. The U-shaped vapor chamber assembly includes a vertical vapor chamber plate and a horizontal vapor chamber plate, and an arc-shaped transition portion 8-1 is arranged at a bent portion between the vertical vapor chamber plate and the horizontal vapor chamber plate. Cavities are formed in both the vertical vapor chamber plate and the horizontal vapor chamber plate. Grooves are formed inside the transition portion 8-1, and the grooves are in communication with the cavities in the vertical vapor chamber plate and the horizontal vapor chamber plate. The inner walls of the grooves are made of a metal mesh or a sintered copper powder. Groove openings face the heat source surface of the vertical power supply module 15. A bottom of the U-shaped vapor chamber assembly is heated, and the vapor in the vapor chamber rises along the transition portion 8-1 and the vertical vapor chamber plate. After condensation by the top heat dissipation device, a condensed liquid can flow back to an evaporation end at the bottom under gravity, thereby avoiding the problem that condensed liquid cannot flow back due to damage to the capillary structure caused by bending of the vapor chamber.

### Embodiment 3

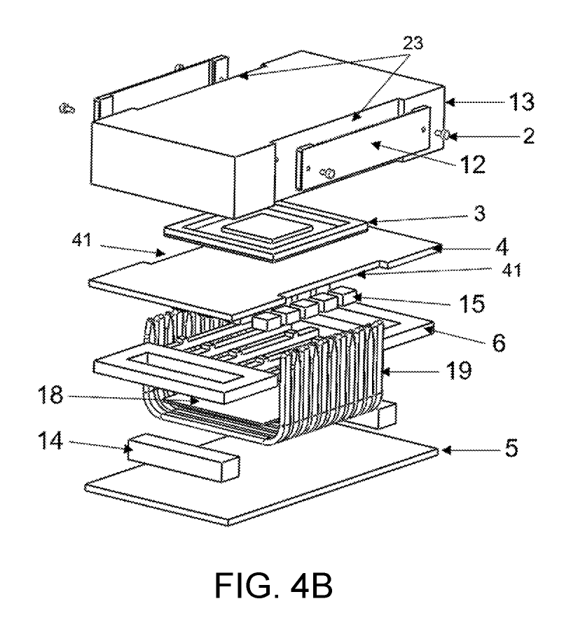

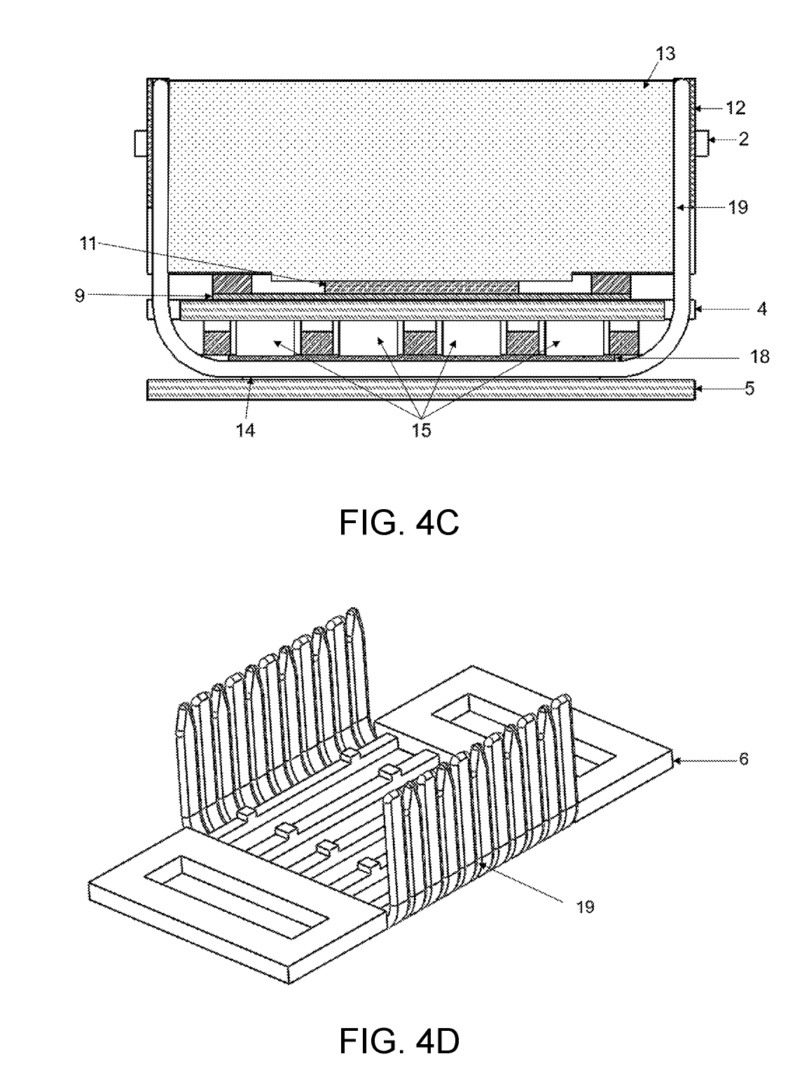

FIG. 4A shows an integrated heat dissipation structure based on a heat pipe plate. The heat transfer composite assembly of this embodiment includes a heat pipe assembly 19, fasteners 12, the stiffening plate 6, a metal sheet 18, and screws 2, as shown in FIGS. 4A to 4C, wherein FIG. 4A is a perspective view of the high-power chip power supply module, FIG. 4B is an exploded view of FIGS. 4A, and 4C is a side sectional view taken along aa'. In this embodiment, the heat pipe assembly 19 replaces the bottom vapor chamber and the longitudinal heat-conducting members in Embodiment 1. The heat pipe assembly 19 is a U-shaped, and its vertical portions are respectively arranged on two opposite sides of the first mainboard 4. The metal sheet 18 are arranged at a bottom of the heat pipe assembly 19 such that a bottom surface of the metal sheet 18 are fixed to and thermally connected with the heat pipe assembly 19, thereby increasing the heat exchange area and fastening the heat pipe. A top surface of the metal sheet 18 are thermally connected to the vertical power supply module 15 through the thermal interface material. Notches 23 are formed on two opposite sides of the top heat dissipation device 13 so that the two vertical portions of the heat pipe assembly 19 are embedded in the notches 23. The top heat dissipation device 13 and the heat pipe assembly 19 are connected by the fasteners 12 and the screws 2, thereby increasing a contact area between the heat pipe assembly 19 and the top heat dissipation device 13 and improving a heat exchange efficiency of the high-power chip power supply module. In addition, the thermal interface material is filled between the heat pipe assembly 19 and the top heat dissipation device 13, thereby reducing a contact thermal resistance therebetween. In this embodiment, the structure of the stiffening plate 6 is the same as that in the foregoing embodiments. Likewise, by using the same process to provide fixing bosses on the top surface of the metal sheet 18 and fixedly connecting them with fixing grooves provided in the bottom surface of the stiffening plate 6, the same technical effects can also be achieved.

In this embodiment, the cavity structure of the U-shaped heat pipe assembly 19 is filled with the phase-change medium, as shown in FIG. 4D. When the heat generated by the vertical power supply module 15 is transferred to the bottom metal sheet 18 and then to the heat pipe assembly 19 through the bottom metal sheet 18, the phase-change medium inside the heat pipe assembly 19 is heated and changes from the liquid state to the gaseous state, then reaches both sides of the heat pipe assembly 19 through the U-shaped cavity. After cooling by the top heat dissipation device, the phase-change medium changes from the gaseous state back to the liquid state and flows back to the bottom of the heat pipe assembly 19. Through this repeated cycle, the heat generated by the vertical power supply module 15 is dissipated through the heat pipe assembly 19 and the top heat dissipation device 13. The heat pipe assembly 19, together with the phase-change medium, effectively reduces the thermal resistance between the vertical power supply module 15 and the top heat dissipation device 13, such that most of the heat generated by the vertical power supply module 15 is transferred to the top heat dissipation device 13 through the heat transfer composite assembly, thereby preventing excessive heat from being transferred to the XPU through the first mainboard 4 and thus reducing the thermal burden on the heat dissipation of the XPU. To ensure effective heat exchange of the phase-change medium in the heat pipe assembly 19, a contact width between the heat pipe assembly 19 and the top heat dissipation device 13 must be greater than or equal to 25 mm, and sufficient thickness must be provided to reduce the resistance imposed by the U-shaped cavity on the diffusion of the phase-change medium.

The thermal interface material according to the present invention includes, but is not limited to, a thermal grease, a thermal pad, or a phase-change material. The metal sheet includes, but are not limited to, a copper, an aluminum, other thermally conductive good conductors, or alloys.

The " equal " or " same " or " equal to " disclosed by the application needs to consider the parameter distribution of engineering, and the error distribution is within +/-30%; and the included angle between the two line segments or the two straight lines is less than or equal to 45 degrees; the included angle between the two line segments or the two straight lines is within the range of [ 60, 120 ]; and the definition of the phase error phase also needs to consider the parameter distribution of the engineering, and the error distribution of the phase error degree is within +/-30%.

The embodiments in the specification are described in a progressive manner, each embodiment focuses on the difference from other embodiments, and the same similar parts between the embodiments can be referred to each other.

The above description of the disclosed embodiments enables a person skilled in the art to implement or use the present application. Various modifications to these embodiments will be readily apparent to those skilled in the art, and the generic principles defined herein may be implemented in other embodiments without departing from the spirit or scope of the application. Thus, the present application will not be limited to the embodiments shown herein but is to be accorded the widest scope consistent with the principles and novel features disclosed herein.

What is claimed is:

1. A heat dissipation structure for a high-power chip power supply module, the high-power chip power supply module comprising:
a first mainboard, comprising a first surface and a second surface opposite to each other;
a high-power chip module disposed on the first surface;
a vertical power supply module having a top surface fixed to the second surface and electrically connected to the first mainboard, the vertical power supply module including at least one heat-generating power component;
a top heat dissipation device thermally coupled to the high-power chip module and vertically aligned with the high-power chip module; and
a bottom heat dissipation device thermally coupled to a bottom surface of the vertical power supply module;
wherein the bottom surface of the vertical power supply module defines a heat dissipation surface, the at least one heat-generating power component is disposed adjacent to the heat dissipation surface, and
wherein the bottom heat dissipation device includes a bottom heat-conducting portion and a vertical heat-conducting portion; the bottom heat-conducting portion being thermally coupled to the heat dissipation surface of the vertical power supply module, the vertical heat-conducting portion being thermally coupled to the top heat dissipation device, such that the bottom heat-conducting portion is thermally coupled to the top heat dissipation device through the vertical heat-conducting portion.

2. The heat dissipation structure of claim 1, wherein the top heat dissipation device comprises a top liquid cooling plate and a thermal interface material, the thermal interface material comprises a thermal grease, a thermal pad, or a phase-change material;
wherein the top heat dissipation device is thermally coupled to the high-power chip module and to the vertical heat-conducting portion of the bottom heat dissipation device through the thermal interface material.

3. The heat dissipation structure of claim 1, wherein the bottom heat dissipation device is U-shaped and includes two vertical heat-conducting portions, the two vertical heat-conducting portions are respectively connected to two ends of the bottom heat-conducting portion and thermally coupled to a side surface of the top heat dissipation device.

4. The heat dissipation structure of claim 3, wherein the bottom heat-conducting portion includes a stiffening plate, the stiffening plate includes a middle slot and a plurality of boss stiffeners disposed in the middle slot;
wherein each of the boss stiffeners includes a top surface and a bottom surface, and each of the plurality of boss stiffeners includes a boss disposed on a top surface thereof; the top surface of each boss is connected to the second surface of the first mainboard;
wherein the vertical power supply module is disposed between adjacent ones of the plurality of boss stiffeners.

5. The heat dissipation structure of claim 3, wherein the bottom heat dissipation device further includes a transition portion disposed between the vertical heat-conducting portion and the bottom heat-conducting portion;
wherein each of the vertical heat-conducting portion and the bottom heat-conducting portion is provided with a cavity;
wherein the transition portion disposes a groove in communication with the cavity of the vertical heat-conducting portion and the cavity of the bottom heat-conducting portion.

6. The heat dissipation structure of claim 5, wherein an inner wall of the groove is made of a metal mesh or a sintered copper powder;
wherein an opening of the groove faces the heat dissipation surface of the vertical power supply module.

7. The heat dissipation structure of claim 6, wherein the cavity is filled with a phase-change material.

8. The heat dissipation structure of claim 4, wherein the bottom heat-conducting portion further includes a bottom vapor chamber thermally coupled to the heat dissipation surface of the vertical power supply module;
wherein bottom surfaces of the plurality of boss stiffeners are fixed to and thermally coupled to the bottom vapor chamber.

9. The heat dissipation structure of claim 8, wherein the bottom surfaces of the plurality of boss stiffeners are fixed to and thermally coupled to the bottom vapor chamber by an epoxy resin adhesive or a silicone adhesive.

10. The heat dissipation structure of claim 8, wherein the bottom heat-conducting portion further includes two horizontal heat-conducting portions respectively connected to the two vertical heat-conducting portions;
wherein bottom surfaces of the two horizontal heat-conducting portions are thermally coupled to the bottom vapor chamber;
wherein the two horizontal heat-conducting portions and the two vertical heat-conducting portions are metal sheets.

11. The heat dissipation structure of claim 10, wherein the bottom surfaces of the two horizontal heat-conducting portions are thermally coupled to the bottom vapor chamber by welding or by a thermally conductive adhesive.

12. The heat dissipation structure of claim 8, wherein the vertical heat-conducting portion is a vertical vapor chamber connected to the bottom vapor chamber;
wherein a cavity defined in the vertical vapor chamber is in communication with a cavity defined in the bottom vapor chamber;
wherein the cavities are filled with a phase-change material.

13. The heat dissipation structure of claim 12, wherein the vertical vapor chamber is connected to the bottom vapor chamber by a brazing, a reflow soldering, or a laser welding.

14. The heat dissipation structure of claim 4, wherein the bottom heat dissipation device includes a U-shaped heat pipe assembly formed by a plurality of U-shaped heat pipes and a bottom metal sheet disposed on an upper surface of the U-shaped heat pipe assembly;
wherein a bottom surface of the bottom metal sheet is thermally coupled to the U-shaped heat pipe assembly;
wherein the heat dissipation surface of the vertical power supply module and bottom surfaces of the plurality of boss stiffeners are thermally coupled to a top surface of the bottom metal sheet;
wherein opposite side portions of the U-shaped heat pipe assembly are thermally coupled to the top heat dissipation device.

15. The heat dissipation structure of claim 14, wherein the U-shaped heat pipe assembly includes a plurality of cavities filled with a phase-change material; wherein a contact width between the U-shaped heat pipe assembly and the top heat dissipation device is greater than or equal to 25 mm.

16. The heat dissipation structure of claim 4, wherein the high-power chip power supply module further comprises a capacitor disposed on the second surface of the first mainboard, the capacitor is arranged corresponding to the plurality of boss stiffeners and disposed between adjacent bosses.

17. The heat dissipation structure of claim 3, wherein the bottom heat dissipation device further includes screws;
wherein the screws extend through screw holes formed in the vertical heat-conducting portion and screw holes formed in the top heat dissipation device to fix and thermally connect to the vertical heat-conducting portion and the top heat dissipation device.

18. The heat dissipation structure of claim 3, wherein the bottom heat dissipation device further includes screws and fasteners;
wherein the top heat dissipation device, the vertical heat-conducting portion, and the fasteners are arranged in sequence;
wherein the screws extend through screw holes formed in the fasteners and screw holes formed in the top heat dissipation device to fix and thermally connect to the vertical heat-conducting portion and the top heat dissipation device.

19. The heat dissipation structure of claim 8, wherein the bottom surface of each of the plurality of boss stiffeners disposes a fixing groove;
wherein a top surface of the bottom vapor chamber includes a fixing boss corresponding to the fixing groove, and the fixing groove and the fixing boss are assembled together.

20. The heat dissipation structure of claim 19, wherein the fixing groove and the fixing boss are assembled by a vacuum diffusion welding or a hot-press sintering.

21. The heat dissipation structure of claim 4, wherein the high-power chip power supply module further comprises a second mainboard and a high-speed signal connector disposed between the first mainboard and the second mainboard;
wherein the first mainboard is electrically connected to the second mainboard through the high-speed signal connector;
wherein the stiffening plate further includes a side slot configured to allow the high-speed signal connector to pass therethrough.

22. The heat dissipation structure of claim 21, wherein the stiffening plate is fixed to the second mainboard by screws.

23. The heat dissipation structure of claim 1, wherein opposite sides of the first mainboard dispose respective clearance regions configured to allow the vertical heat-conducting portion to bypass the first mainboard and be thermally connected to the top heat dissipation device.

24. The heat dissipation structure of claim 18, wherein opposite sides of the top heat dissipation device dispose respective notches configured to receive the vertical heat-conducting portion.

25. The heat dissipation structure of claim 1, wherein a contact width between the vertical heat-conducting portion and the top heat dissipation device is greater than or equal to 10 mm.
